(19) United States
(12) Patent Application Publication
(10) Pub. No.: US 2025/0175203 A1
(43) Pub. Date: May 29, 2025

(54) HIGH FREQUENCY MODULE AND COMMUNICATION DEVICE

(71) Applicant: Murata Manufacturing Co., Ltd., Nagaokakyo-shi (JP)

(72) Inventors: Takanori UEJIMA, Nagaokakyo-shi (JP); Kazuya OKAMOTO, Nagaokakyo-shi (JP)

(73) Assignee: Murata Manufacturing Co., Ltd., Nagaokakyo-shi (JP)

(21) Appl. No.: 18/953,062

(22) Filed: Nov. 20, 2024

(30) Foreign Application Priority Data
Nov. 27, 2023 (JP) 2023-200072

(51) Int. Cl. H04B 1/04; H05K 1/02; H05K 3/40

(52) U.S. Cl. CPC H04B 1/04; H05K 1/0243; H05K 3/4007; H04B 2001/0408

(57) ABSTRACT

A high frequency module includes a mounting substrate; and a power amplifier. The mounting substrate includes a first main surface and a second main surface. The first main surface and the second main surface face each other. The power amplifier is disposed on the first main surface of the mounting substrate and includes an RF bump and a ground bump. The ground bump is higher than the RF bump. The mounting substrate includes a first recess portion. The first recess portion is formed on the first main surface of the mounting substrate. The ground bump is disposed in the first recess portion of the mounting substrate.

### CROSS-REFERENCE TO RELATED APPLICATION

The present application claims priority to Japanese patent application no. JP 2023-200072 filed Nov. 27, 2023, the entire content of which is incorporated herein by reference.

### BACKGROUND

### 1. Field

The present disclosure generally relates to a high frequency module and a communication device, and more particularly relates to a high frequency module including a power amplifier and a communication device including the high frequency module.

### 2. Description of the Related Art

Japanese Unexamined Patent Application Publication (Translation of PCT Application) No. 2017-515295 describes a passive on-package including a substrate having a recess portion. In the passive on-package described in Japanese Unexamined Patent Application Publication (Translation of PCT Application) No. 2017-515295, a bump is disposed in the recess portion of the substrate.

### SUMMARY

However, in the passive on-package in the related art described in Japanese Unexamined Patent Application Publication (Translation of PCT Application) No. 2017-515295, it is difficult to achieve low profile of the high frequency module in which the electronic component such as the passive on-package is disposed on the mounting substrate.

The present disclosure has been made in view of the above points, and an exemplary embodiment is to provide a high frequency module and a communication device capable of achieving low profile.

A high frequency module according to the present disclosure includes: a mounting substrate; and a power amplifier. The mounting substrate includes a first main surface and a second main surface. The first main surface and the second main surface face each other. The power amplifier is disposed on the first main surface of the mounting substrate and includes an RF bump and a ground bump. The ground bump is higher than the RF bump. The mounting substrate includes a first recess portion. The first recess portion is formed on the first main surface of the mounting substrate. The ground bump is disposed in the first recess portion of the mounting substrate.

A communication device according to the present disclosure includes the high frequency module and a signal processing circuit. The signal processing circuit is connected to the high frequency module.

According to the high frequency module and the communication device according to one or more aspects of the present disclosure, it is possible to achieve low profile of the high frequency module.

### BRIEF DESCRIPTION OF THE DRAWINGS

FIG. 1 is a cross-sectional view of a high frequency module according to Embodiment 1;

FIG. 2 is a bottom view of the power amplifier of the above high frequency module;

FIG. 3 is a plan view of the mounting substrate of the above high frequency module;

FIG. 4 is a block diagram of a communication device according to Embodiment 1;

FIG. 5 is a cross-sectional view of a high frequency module according to Embodiment 2;

FIG. 6 is a cross-sectional view of a high frequency module according to Embodiment 3;

FIG. 7 is a plan view of a main part of a mounting substrate of a high frequency module according to Embodiment 4;

FIG. 8A is a cross-sectional view of a main part of a mounting substrate of a high frequency module according to Embodiment 5.

FIG. 8B is a cross-sectional view of a main part of a mounting substrate of a high frequency module according to Modification Example 1 of Embodiment 5.

FIG. 8C is a cross-sectional view of a main part of a mounting substrate of a high frequency module according to Modification Example 2 of Embodiment 5;

FIG. 9 is a plan view of a main part of a mounting substrate of a high frequency module according to Embodiment 6; and

FIG. 10 is a cross-sectional view of a high frequency module according to Embodiment 7.

### DETAILED DESCRIPTION

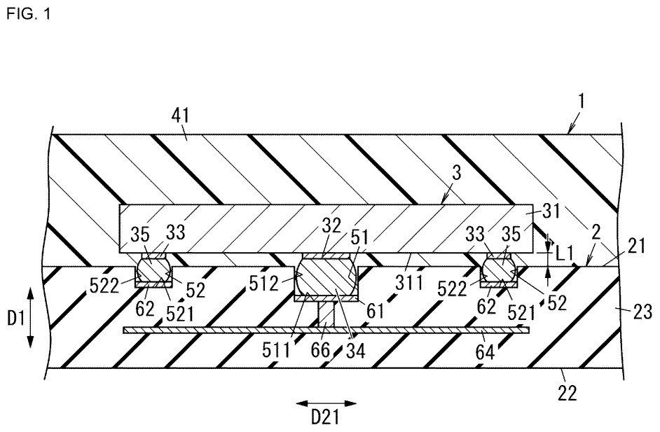

Hereinafter, a high frequency module 1 and a communication device 8 according to Embodiments 1 to 7 will be described with reference to the accompanying drawings. FIGS. 1 to 3 and 5 to 10 referred to in the following embodiments and the like are schematic diagrams, and each ratio of a size or a thickness of each component in FIGS. 1 to 3 and 5 to 10 does not necessarily reflect an actual dimensional ratio.

### Embodiment 1

### (1) High Frequency Module

A configuration of the high frequency module 1 according to Embodiment 1 will be described with reference to the drawings.

The high frequency module 1 according to Embodiment 1 includes a mounting substrate 2, a power amplifier 3, and a resin layer 41, as shown in FIG. 1. The mounting substrate 2 includes a first main surface 21 and a second main surface 22. The first main surface 21 and the second main surface 22 face each other. The power amplifier 3 is disposed on the first main surface 21 of the mounting substrate 2. The power amplifier 3 includes a plurality of RF bumps 35 and a ground bump 34. The ground bump 34 is higher than the plurality of RF bumps 35. The mounting substrate 2 includes a first recess portion 51. The first recess portion 51 is formed on the first main surface 21 of the mounting substrate 2. The ground bump 34 is disposed in the first recess portion 51 of the mounting substrate 2.

With the high frequency module 1 according to Embodiment 1, it is possible to achieve low profile of the high frequency module 1.

### (2) Each Component of High Frequency Module

Hereinafter, each of the components of the high frequency module 1 according to Embodiment 1 will be described with reference to the drawings.

As shown in FIG. 1, the high frequency module 1 according to Embodiment 1 includes the mounting substrate 2, the power amplifier 3, the resin layer 41, and a plurality of external connection terminals.

### (2.1) Mounting Substrate

As shown in FIG. 1, the mounting substrate 2 includes the first main surface 21 and the second main surface 22. The first main surface 21 and the second main surface 22 face each other. More specifically, the first main surface 21 and the second main surface 22 face each other in a thickness direction D1 of the mounting substrate 2. The mounting substrate 2 is a substrate for mounting the plurality of electronic components, and has, for example, a rectangular plate shape. The first main surface 21 and the second main surface 22 are, for example, rectangular. The second main surface 22 faces an external substrate in a case that the high frequency module 1 is provided on the external substrate.

The mounting substrate 2 includes a plurality of dielectric layers 23 and a plurality of conductive layers. The mounting substrate 2 is, for example, a multilayer substrate having a plurality of dielectric layers 23 and a plurality of conductive layers. The plurality of dielectric layers 23 and the plurality of conductive layers are laminated in the thickness direction D1 of the mounting substrate 2.

Each of the plurality of conductive layers includes one or a plurality of conductor portions in one plane orthogonal to the thickness direction D1 of the mounting substrate 2. The plurality of conductive layers are formed in a predetermined pattern determined for each layer. A material of each conductive layer is, for example, copper.

The plurality of conductive layers include a ground layer 64. The ground layer 64 is a layer set to a ground potential (reference potential), and is provided inside the mounting substrate 2. In a case that the high frequency module 1 is disposed on the external substrate (for example, a motherboard), the ground layer 64 is connected to the ground of the external substrate with the via conductor or the like of the mounting substrate 2 interposed therebetween and is maintained at a ground potential (reference potential).

The mounting substrate 2 is, for example, a low temperature co-fired ceramics (LTCC) substrate. The mounting substrate 2 is not limited to the LTCC substrate, and may be, for example, a printed wiring board, a high temperature co-fired ceramics (HTCC) substrate, or a resin multilayer substrate.

### (2.2) Power Amplifier

As shown in FIG. 1, the power amplifier 3 is disposed on the first main surface 21 of the mounting substrate 2. More specifically, the power amplifier 3 is mounted on the first main surface 21 of the mounting substrate 2. The power amplifier 3 amplifies a transmission signal from a signal processing circuit 82 (refer to FIG. 4) and outputs the transmission signal.

As shown in FIGS. 1 to 3, the power amplifier 3 includes a main body portion 31, a plurality of electrodes 32 and 33, the ground bump 34, and the plurality of RF bumps 35. The power amplifier 3 is disposed on the first main surface 21 of the mounting substrate 2 by connecting the plurality of electrodes 32 and 33 to a first electrode 61 and a plurality of second electrodes 62 provided on the first main surface 21 of the mounting substrate 2 with the ground bump 34 and the plurality of RF bumps 35 interposed therebetween.

The main body portion 31 has a functional unit. The main body portion 31 is disposed on the mounting substrate 2 such that one main surface 311 of the main body portion 31 faces the mounting substrate 2 in the thickness direction D1 of the mounting substrate 2. More specifically, one main surface 311 of the main body portion 31 faces the first main surface 21 of the mounting substrate 2 in a state where the power amplifier 3 is disposed on the mounting substrate 2.

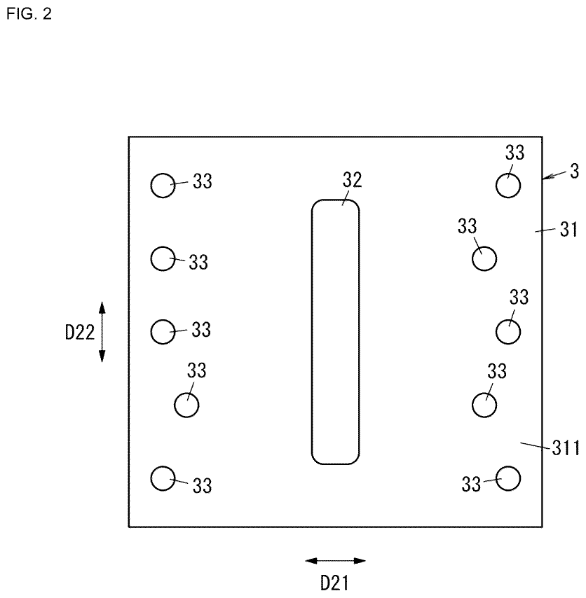

The electrode 32 is formed on one main surface 311 of the main body portion 31. One main surface 311 of the main body portion 31 faces the mounting substrate 2 in the thickness direction D1 of the mounting substrate 2. The electrode 32 is formed, for example, in an elongated shape. In the example of FIG. 2, the electrode 32 is formed in an elongated shape along a second direction D22.

The plurality of electrodes 33 are formed on one main surface 311 of the main body portion 31. The plurality of electrodes 33 are provided, for example, on one main surface 311 of the main body portion 31 around the electrode 32. For example, the plurality of electrodes 33 are provided on both sides of the electrode 32 in a first direction D21.

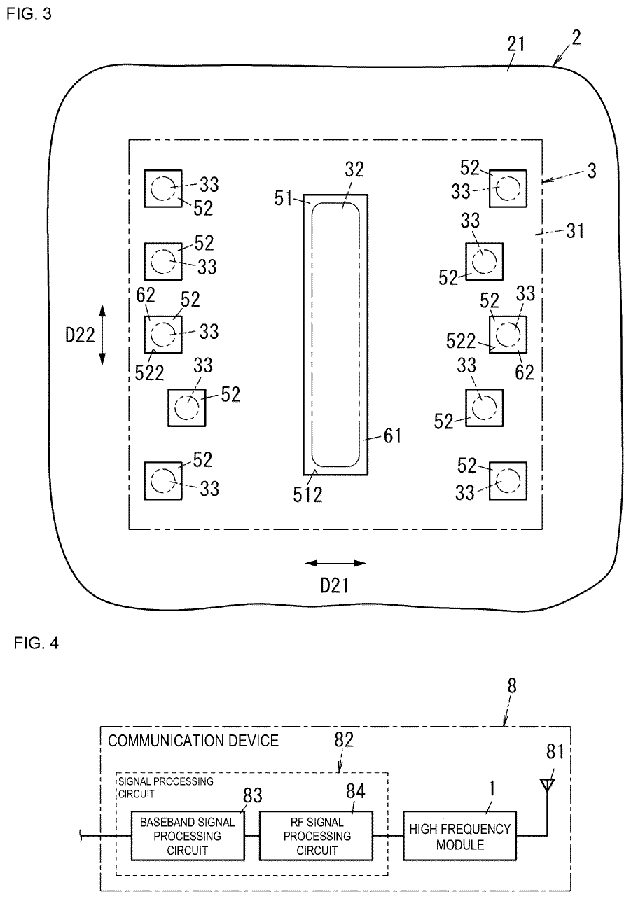

The electrode 32 is an electrode for the ground. In order to stabilize the ground potential, the size of the electrode for the ground can be increased. Therefore, as shown in FIGS. 2 and 3, in a plan view from a normal direction of one main surface 311 on which the electrode 32 and the plurality of electrodes 33 are disposed, an area of the electrode 32 is larger than an area of each electrode 33. That is, the area of the electrode 32 for the ground is larger than the area of the electrode 33 for the RF signal.

As shown in FIG. 1, the ground bump 34 is a bump for connecting the electrode 32 for the ground to the ground layer 64 of the mounting substrate 2. The ground bump 34 is disposed on the electrode 32. The ground bump 34 is formed in, for example, a circular shape. The ground bump 34 is formed of, for example, solder.

The plurality of RF bumps 35 are conductive members for connecting the plurality of electrodes 33 for the RF signal and the conductive layer of the mounting substrate 2. The plurality of RF bumps 35 are formed on the plurality of electrodes 33. The plurality of RF bumps 35 are formed of, for example, solder.

The power amplifier 3 is, for example, an IC chip including a substrate and an amplification functional unit. The substrate includes a first surface and a second surface that face each other. The substrate is, for example, a gallium arsenide substrate. The amplification functional unit includes at least one transistor formed on the first surface of the substrate. The amplification functional unit is a functional unit having a function of amplifying a transmission signal in a predetermined frequency band. The transistor is, for example, a heterojunction bipolar transistor (HBT). In the power amplifier 3, a power voltage from a power supply circuit is applied between the collector and the emitter of the HBT. The power amplifier 3 may include, for example, a DC cut capacitor, in addition to the amplification functional unit. The power amplifier 3 is provided with, for example, a flip-chip mounted on the first main surface 21 of the mounting substrate 2 such that the first surface of the substrate is on the first main surface 21 side of the mounting substrate 2. In a plan view in the thickness direction D1 of the mounting substrate 2, an outer peripheral shape of the power amplifier 3 is a quadrangular shape.

### (2.3) Arrangement Relationship Between Mounting Substrate and Power Amplifier

As shown in FIG. 1, the mounting substrate 2 includes the first recess portion 51 and a plurality of second recess portions 52. The first recess portion 51 is formed on the first main surface 21 of the mounting substrate 2. The first recess portion 51 includes a bottom surface 511 and a side surface 512. The plurality of second recess portions 52 are formed on the first main surface 21 of the mounting substrate 2. Each of the plurality of second recess portions 52 includes a bottom surface 521 and a side surface 522.

The mounting substrate 2 includes the first electrode 61 and the plurality of second electrodes 62. The first electrode 61 is disposed in the first recess portion 51. More specifically, the first electrode 61 is disposed on the bottom surface 511 of the first recess portion 51. The plurality of second electrodes 62 are disposed in the plurality of second recess portions 52. More specifically, the plurality of second electrodes 62 are disposed on the bottom surfaces 521 of the plurality of second recess portions 52.

The ground bump 34 of the power amplifier 3 is disposed in the first recess portion 51 of the mounting substrate 2. More specifically, in the ground bump 34, the ground bump 34 is disposed in the first recess portion 51 such that at least a part of the ground bump 34 is accommodated in the first recess portion 51.

Since the ground bump 34 of the power amplifier 3 is disposed in the first recess portion 51 of the mounting substrate 2, the height of the power amplifier 3 from the surface of the first main surface 21 of the mounting substrate 2 on which the first recess portion 51 and the second recess portion 52 are not formed can be reduced, and thus it is possible to achieve low profile of the high frequency module 1.

The plurality of RF bumps 35 of the power amplifier 3 are disposed in the plurality of second recess portions 52 of the mounting substrate 2. More specifically, in each of the plurality of RF bumps 35, at least a part of the RF bump 35 is accommodated in the second recess portion 52, and the RF bump 35 is disposed in the second recess portion 52.

Since the plurality of RF bumps 35 of the power amplifier 3 are disposed in the plurality of second recess portions 52 of the mounting substrate 2, the height of the power amplifier 3 from the surface of the first main surface 21 of the mounting substrate 2 on which the first recess portion 51 and the second recess portion 52 are not formed can be further reduced, and thus the low profile of the high frequency module 1 can be achieved.

As described above, in a plan view from a normal direction of one main surface 311 on which the ground bump 34 and the plurality of RF bumps 35 are disposed, the area of the electrode 32 for the ground is larger than the area of the electrode 33 for the RF signal. Since the ground bump 34 covers the electrode 32 having a large area, the area of the ground bump 34 is larger than the area of each RF bump 35. Therefore, as shown in FIG. 1, in the normal direction of one main surface 311 of the power amplifier 3, that is, in the thickness direction D1 of the mounting substrate 2, the height of the ground bump 34 is higher than the height of each of the plurality of RF bumps 35.

The first recess portion 51 of the mounting substrate 2 is deeper in the thickness direction D1 of the mounting substrate 2 than each of the plurality of second recess portions 52. Accordingly, the ground bump 34 larger than each RF bump 35 can be disposed in the first recess portion 51 deeper than each second recess portion 52.

The mounting substrate 2 further includes a plurality of via conductors 66. The plurality of via conductors 66 are, for example, columnar conductive members, and are provided inside the mounting substrate 2. The plurality of via conductors 66 are used for the electrical connection between the electronic components disposed on the first main surface 21 of the mounting substrate 2 and the conductive layer of the mounting substrate 2. In addition, the plurality of via conductors 66 are used for electrically connecting the conductive layer of the mounting substrate 2 to an external connection terminal.

The via conductor 66 shown in FIG. 1 is connected to the first recess portion 51 in which the ground bump 34 is disposed. The via conductor 66 is used for the electrical connection between the power amplifier 3 disposed on the first main surface 21 of the mounting substrate 2 and the ground layer 64 of the mounting substrate 2.

Since the via conductor 66 is connected to the first recess portion 51 in which the ground bump 34 is disposed, the length of the via conductor 66 can be made shorter than in a case where the first recess portion 51 is not formed, and thus, for example, the distance from the ground bump 34 to the ground layer 64 can be made shorter.

The power amplifier 3 includes the main body portion 31 having a functional unit. The main body portion 31 of the power amplifier 3 is positioned outside the mounting substrate 2.

As a result, the strength of the mounting substrate 2 can be increased as compared with a case where the recess portion accommodating the main body portion 31 of the power amplifier 3 is formed in the mounting substrate 2.

### (2.4) Resin Layer

As shown in FIG. 1, the resin layer 41 is disposed on the first main surface 21 of the mounting substrate 2. The resin layer 41 is in contact with the first main surface 21 of the mounting substrate 2 and covers at least a part of the power amplifier 3. As a result, the mounting substrate 2 and the power amplifier 3 can be protected.

The resin layer 41 contains a resin and a filler. The resin is, for example, an epoxy resin. In the high frequency module 1, the distance L1 between the main body portion 31 of the power amplifier 3 and the mounting substrate 2 is larger than the diameter of the filler contained in the resin layer 41. As a result, the resin layer 41 intrudes into the periphery of the bump (the ground bump 34 and the RF bump 35) of the power amplifier 3, and thus the solder splash can be prevented in a case that the high frequency module 1 is mounted on the motherboard. As a result, it is possible to improve the connection reliability of the power amplifier 3.

### (2.5) External Connection Terminal

The plurality of external connection terminals are disposed on the second main surface 22 of the mounting substrate 2, for example. The plurality of external connection terminals are terminals for electrically connecting the mounting substrate 2 and the external substrate. The plurality of external connection terminals are arranged on the second main surface 22 of the mounting substrate 2 at intervals from each other.

Each of the plurality of external connection terminals is a flat plate-shaped conductive member. Materials of the plurality of external connection terminals are, for example, metal (for example, copper, copper alloy, or the like).

Each of the external connection terminals is connected to an external connection electrode of the external substrate. In the present specification and the like, the expression “A (for example, an external connection terminal) is connected to B (for example, an external connection electrode of an external substrate)” means not only that A and B are in contact with each other but also that A and B are electrically connected to each other with a conductor electrode, a conductor terminal, a wiring, or another circuit component interposed therebetween. The plurality of the external connection terminals are connected to the external connection electrodes of the external substrate with a connection member (for example, a solder bump) formed of a conductor, for example, interposed therebetween.

The plurality of external connection terminals include an antenna terminal, a signal input terminal, a signal output terminal, a control terminal, and a ground terminal. The antenna terminal is a terminal to which the antenna 81 (refer to FIG. 4) is connected. The signal input terminal is a terminal for inputting a transmission signal (high frequency signal) from the signal processing circuit 82 (refer to FIG. 4) to the high frequency module 1. The signal output terminal is a terminal for outputting the reception signal (high frequency signal) from the high frequency module 1 to the signal processing circuit 82. The control terminal is a terminal for inputting a control signal from the signal processing circuit 82 to a controller.

### (3) Communication Device

As shown in FIG. 4, the communication device 8 includes the high frequency module 1, the antenna 81, and the signal processing circuit 82. The communication device 8 is, for example, a mobile terminal (for example, a smartphone). It should be noted that the communication device 8 is not limited to the mobile terminal, and may be, for example, a wearable terminal (for example, a smart watch).

The high frequency module 1 is configured to amplify a transmission signal (high frequency signal) from the signal processing circuit 82 and output the amplified transmission signal to the antenna 81. The high frequency module 1 is configured to amplify a reception signal (high frequency signal), which is received by the antenna 81, and output the amplified reception signal to the signal processing circuit 82. The high frequency module 1 is controlled by the signal processing circuit 82, for example.

The high frequency module 1 is a module compatible with, for example, a 4G (fourth generation mobile communication) standard and a 5G (fifth generation mobile communication) standard. The 4G standard is, for example, a third generation partnership project (3GPP, registered trademark) long term evolution (LTE, registered trademark) standard. The 5G standard is, for example, 5G new radio (NR). The high frequency module 1 is a module compatible with carrier aggregation and dual connectivity.

In the communication device 8, the high frequency module 1 can be electrically connected to an external substrate. The external substrate corresponds to, for example, a motherboard of a mobile terminal, a communication device, or the like. The fact that the high frequency module 1 can be electrically connected to the external substrate includes not only a case where the high frequency module 1 is directly mounted on the external substrate but also a case where the high frequency module 1 is indirectly mounted on the external substrate. The case where the high frequency module 1 is indirectly mounted on the external substrate is a case where the high frequency module 1 is mounted on another high frequency module mounted on the external substrate, or the like.

### (3.1) Antenna

The antenna 81 is connected to an antenna terminal of the high frequency module 1. The antenna 81 has a transmission function of emitting the transmission signal output from the high frequency module 1 as a radio wave, and a reception function of receiving the reception signal from an outside as a radio wave and outputting the reception signal to the high frequency module 1.

### (3.2) Signal Processing Circuit

The signal processing circuit 82 is connected to the high frequency module 1. The signal processing circuit 82 processes a high frequency signal passing through the high frequency module 1. More specifically, the signal processing circuit 82 is configured to perform signal processing on the reception signal received from the high frequency module 1. Further, the signal processing circuit 82 is configured to perform the signal processing on the transmission signal to be output to the high frequency module 1.

The signal processing circuit 82 includes a baseband signal processing circuit 83 and an RF signal processing circuit 84.

For example, the baseband signal processing circuit 83 is a baseband integrated circuit (BBIC).

The baseband signal processing circuit 83 performs predetermined signal processing on a signal from the outside of the signal processing circuit 82. More specifically, the baseband signal processing circuit 83 generates the transmission signal from the baseband signal (for example, the audio signal and the image signal) from the outside of the signal processing circuit 82, and outputs the generated transmission signal to the RF signal processing circuit 84.

The baseband signal processing circuit 83 performs predetermined signal processing on a signal from the RF signal processing circuit 84. More specifically, the baseband signal processing circuit 83 outputs the reception signal received from the RF signal processing circuit 84 to the outside. For example, the reception signal processed by the baseband signal processing circuit 83 is used as an image signal for an image display, or is used as an audio signal for a conversation.

The RF signal processing circuit 84 is, for example, a radio frequency integrated circuit (RFIC) and performs the signal processing on the high frequency signal (the transmission signal and the reception signal).

The RF signal processing circuit 84 performs signal processing on the transmission signal output from the baseband signal processing circuit 83 and outputs the transmission signal on which the signal processing has been performed to the high frequency module 1. Specifically, the RF signal processing circuit 84 performs signal processing, such as up-conversion, on a transmission signal output from the baseband signal processing circuit 83, and outputs the transmission signal on which the signal processing is performed to the transmission path of the high frequency module 1.

The RF signal processing circuit 84 performs signal processing on the reception signal output from the high frequency module 1 and outputs the reception signal on which the signal processing has been performed to the baseband signal processing circuit 83. Specifically, the RF signal processing circuit 84 performs signal processing, such as down-conversion, on the reception signal output from the reception path of the high frequency module 1, and outputs the reception signal on which the signal processing is performed to the baseband signal processing circuit 83.

### (4) Effects

In the high frequency module 1 according to Embodiment 1, the ground bump 34 of the power amplifier 3 is disposed in the first recess portion 51 of the mounting substrate 2. As a result, the height of the power amplifier 3 from the surface of the first main surface 21 of the mounting substrate 2 on which the first recess portion 51 and the second recess portion 52 are not formed can be reduced, and thus it is possible to achieve low profile of the high frequency module 1.

In the high frequency module 1 according to Embodiment 1, the first recess portion 51 is formed in the mounting substrate 2. As a result, the distance between the power amplifier 3 and the wiring conductor or the wiring element built in the mounting substrate 2 can be made shorter than in a case where the first recess portion 51 is not formed.

In the high frequency module 1 according to Embodiment 1, the ground bump 34 is disposed in the first recess portion 51 of the mounting substrate 2, and the RF bump 35 is disposed in the second recess portion 52 of the mounting substrate 2. As a result, the height of the power amplifier 3 from the surface of the first main surface 21 of the mounting substrate 2 on which the first recess portion 51 and the second recess portion 52 are not formed can further be reduced, and thus it is possible to further achieve low profile of the high frequency module 1.

In the high frequency module 1 according to Embodiment 1, the second recess portion 52 is formed in the mounting substrate 2. As a result, the distance between the power amplifier 3 and the wiring conductor or the wiring element built in the mounting substrate 2 can be made shorter than in a case where the second recess portion 52 is not formed.

In the high frequency module 1 according to Embodiment 1, the via conductor 66 is provided in the first recess portion 51 in which the ground bump 34 is disposed. As a result, the length of the via conductor 66 can be made shorter than in a case where the first recess portion 51 is not formed, and thus, for example, the distance from the ground bump 34 to the ground layer 64 of the mounting substrate 2 can be made shorter.

In the high frequency module 1 according to Embodiment 1, the resin layer 41 is provided in contact with the first main surface 21 of the mounting substrate 2 and covering at least a part of the power amplifier 3. As a result, the mounting substrate 2 and the power amplifier 3 can be protected.

In the high frequency module 1 according to Embodiment 1, a distance L1 between the main body portion 31 of the power amplifier 3 and the mounting substrate 2 is larger than the diameter of the filler included in the resin layer 41. As a result, the resin layer 41 intrudes into the periphery of the bump of the power amplifier 3, and thus it is possible to prevent the solder splash in a case that the high frequency module 1 is mounted on the motherboard. As a result, it is possible to improve the connection reliability of the power amplifier 3.

In the high frequency module 1 according to Embodiment 1, the main body portion 31 of the power amplifier 3 is positioned outside the mounting substrate 2. As a result, the strength of the mounting substrate 2 can be increased as compared with a case where the recess portion accommodating the main body portion 31 of the power amplifier 3 is formed in the mounting substrate 2.

With the high frequency module 1 according to Embodiment 1, the low profile of the high frequency module 1 can be achieved only by performing processing on the mounting substrate 2 even in a case where the power amplifiers 3 having different sizes are disposed on the mounting substrate 2. In other words, the low profile of the high frequency module 1 can be achieved only by performing processing of forming the first recess portion 51 and the second recess portion 52 of the mounting substrate 2.

In the high frequency module 1 according to Embodiment 1, the ground bump 34 is disposed in the first recess portion 51, and at least a part of the solder of the ground bump 34 fills the first recess portion 51. As a result, the total of the thickness of the mounting substrate 2 and the thickness of the ground bump 34 can be increased as compared with a case where the ground bump 34 is not disposed in the first recess portion 51, and thus the strength of the mounting substrate 2 can be increased.

In the high frequency module 1 according to Embodiment 1, the RF bump 35 is disposed in the second recess portion 52, and at least a part of the solder of the RF bump 35 fills the second recess portion 52. As a result, the total of the thickness of the mounting substrate 2 and the thickness of the RF bump 35 can be increased as compared with a case where the RF bump 35 is not disposed in the second recess portion 52, and thus the strength of the mounting substrate 2 can be increased.

In the high frequency module 1 according to Embodiment 1, the first recess portion 51 and the second recess portion 52 are formed on the mounting substrate 2, and the ground bump 34 and the RF bump 35 that protrude from one main surface 311 of the main body portion 31 are provided in the power amplifier 3. As a result, it is possible to reduce the non-leveling of the first main surface 21 of the mounting substrate 2 on which the power amplifier 3 is disposed.

In the high frequency module 1 according to Embodiment 1, since the first recess portion 51 and the second recess portion 52 are provided in the mounting substrate 2, the operation amount of the self-alignment generated in a case that the solder of the ground bump 34 and the plurality of RF bumps 35 is melted can be limited to within the first recess portion 51 and the second recess portion 52, and thus it is possible to improve the mountability of the power amplifier 3 on the mounting substrate 2.

In the high frequency module 1 according to Embodiment 1, the first recess portion 51 and the second recess portion 52 are formed on the mounting substrate 2. As a result, compared to a case where the first recess portion 51 and the second recess portion 52 are not formed, the thickness of the mounting substrate 2 can be increased while maintaining the height of the high frequency module 1, and thus the strength of the mounting substrate 2 can be increased.

In the communication device 8 according to Embodiment 1, in the high frequency module 1, the ground bump 34 of the power amplifier 3 is disposed in the first recess portion 51 of the mounting substrate 2. As a result, it is possible to achieve low profile of the high frequency module 1.

### (5) Modification Examples

Hereinafter, modification examples of Embodiment 1 will be described.

### (5.1) Modification Example 1

The high frequency module 1 according to Modification Example 1 of Embodiment 1 includes the mounting substrate 2, the power amplifier 3, the resin layer 41, a plurality of external connection terminals, and a shield layer.

The shield layer covers at least a part of the resin layer 41 and the mounting substrate 2. More specifically, the shield layer covers one main surface and an outer peripheral surface of the resin layer 41 and an outer peripheral surface of the mounting substrate 2. One main surface of the resin layer 41 is a main surface on a side opposite to the mounting substrate 2 side in the resin layer 41.

The shield layer has conductivity. More specifically, the shield layer has a multilayer structure in which a plurality of metal layers are laminated. The metal layer includes one or more types of metals. The shield layer is not limited to the above-described multilayer structure, and may be one metal layer.

The shield layer is provided, for example, for the purpose of providing an electromagnetic shield between the inside and the outside of the high frequency module 1. The shield layer is in contact with at least a part of the ground layer of the mounting substrate 2. Therefore, it is possible to set the potential of the shield layer to be equal to the potential of the ground layer.

The shield layer covers at least a part of a main surface of the power amplifier 3. The shield layer may be connected to the main surface of the power amplifier 3, for example, by coming into contact with the main surface of the power amplifier 3.

### (5.2) Modification Example 2

In the high frequency module 1 according to Modification Example 2 of Embodiment 1, the distance L1 (refer to FIG. 1) between the main body portion 31 of the power amplifier 3 and the mounting substrate 2 is smaller than the diameter of the filler included in the resin layer 41.

With the high frequency module 1 according to Modification Example 2 of Embodiment 1, it is possible to further achieve low profile of the high frequency module 1.

### (5.3) Modification Example 3

In the high frequency module 1 according to Modification Example 3 of Embodiment 1, the resin layer 41 does not contain the filler. The resin layer 41 contains, for example, no filler and contains only a resin.

The high frequency module 1 according to each of the above-described modification examples also has the same effects as the high frequency module 1 according to Embodiment 1.

### Embodiment 2

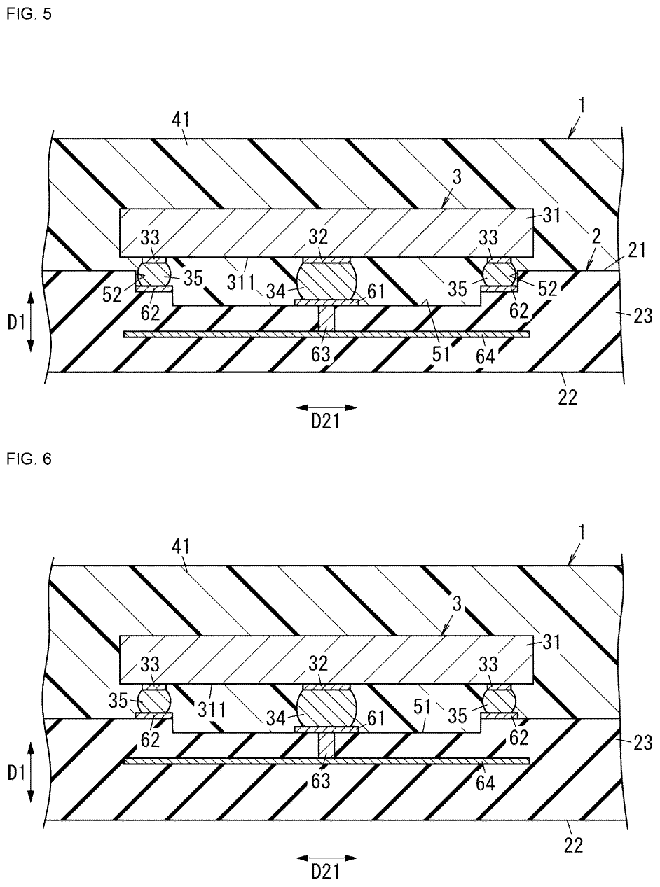

The high frequency module 1 according to Embodiment 2 is different from the high frequency module 1 (refer to FIG. 1) according to Embodiment 1 in that the first recess portion 51 and the plurality of second recess portions 52 of the mounting substrate 2 are continuous to each other, as shown in FIG. 5. Regarding the high frequency module 1 according to Embodiment 2, the same components as the high frequency module 1 according to Embodiment 1 are attached with the same reference numerals, and the description thereof will be omitted.

### (1) Configuration

In the mounting substrate 2 according to Embodiment 2, as shown in FIG. 5, the first recess portion 51 and the plurality of second recess portions 52 are continuous to each other.

In a state where the first recess portion 51 and the plurality of second recess portions 52 are continuous to each other, the depth of the first recess portion 51 is deeper than the depth of each second recess portion 52. That is, a step is formed in the vicinity of the boundary between the first recess portion 51 and each of the second recess portions 52.

Regarding the mounting substrate 2 of Embodiment 2, the same configuration and function as those of the mounting substrate 2 (refer to FIG. 1) of Embodiment 1 will not be described.

### (2) Effects

In the high frequency module 1 according to Embodiment 2, the first recess portion 51 and the plurality of second recess portions 52 are continuous to each other on the mounting substrate 2. As a result, it is not necessary to form a wall between the first recess portion 51 and each of the second recess portions 52, and thus the first recess portion 51 and the plurality of second recess portions 52 can be easily formed.

In the high frequency module 1 according to Embodiment 2, the first recess portion 51 and the plurality of second recess portions 52 are continuous to each other on the mounting substrate 2. As a result, the first recess portion 51 and each of the second recess portions 52 can be formed even in a case where the distance between the two electrodes 32 and 33 adjacent to each other in the plane direction of one main surface 311 of the power amplifier 3 (for example, the first direction D21 and the second direction D22) is short, that is, in a case where the distance between the ground bump 34 and the RF bump 35 is short.

### (3) Modification Examples

Hereinafter, modification examples of Embodiment 2 will be described.

The high frequency module 1 according to the modification example of Embodiment 2 further includes a shield layer as in the high frequency module 1 according to Modification Example 1 of Embodiment 1.

The high frequency module 1 according to the modification example described above also has the same effects as the high frequency module 1 according to Embodiment 2.

### Embodiment 3

The high frequency module 1 according to Embodiment 3 is different from the high frequency module 1 (refer to FIG. 1) according to Embodiment 1 in that the plurality of second recess portions 52 (refer to FIG. 1) of the mounting substrate 2 are not provided, as shown in FIG. 6. Regarding the high frequency module 1 according to Embodiment 3, the same components as the high frequency module 1 according to Embodiment 1 are attached with the same reference numerals, and the description thereof will be omitted.

### (1) Configuration

In the mounting substrate 2 according to Embodiment 3, as shown in FIG. 6, a plurality of second recess portions 52 (refer to FIG. 1) are not provided.

The plurality of second electrodes 62 according to Embodiment 3 are disposed at a part of the first main surface 21 of the mounting substrate 2 on which the recess portion is not formed.

The plurality of RF bumps 35 are disposed on the plurality of second electrodes 62. That is, the plurality of RF bumps 35 are disposed at a part of the first main surface 21 of the mounting substrate 2 on which the recess portion is not formed.

Regarding the mounting substrate 2 of Embodiment 3, the same configuration and function as those of the mounting substrate 2 (refer to FIG. 1) of Embodiment 1 will not be described.

### (2) Effects

In the high frequency module 1 according to Embodiment 3, the plurality of second recess portions 52 are not provided. As a result, the processing of forming the recess portion with respect to the mounting substrate 2 can be simplified.

### (3) Modification Examples

Hereinafter, modification examples of Embodiment 3 will be described.

The high frequency module 1 according to the modification example of Embodiment 3 further includes a shield layer as in the high frequency module 1 according to the modification examples of Embodiment 1.

The high frequency module 1 according to the modification example described above also has the same effects as the high frequency module 1 according to Embodiment 3.

### Embodiment 4

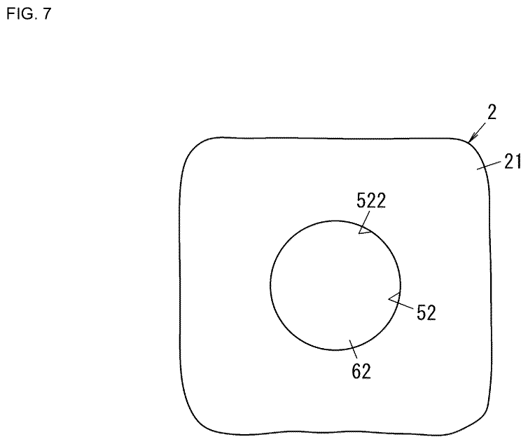

The high frequency module 1 according to Embodiment 4 is different from the high frequency module 1 (refer to FIG. 1) according to Embodiment 1 in that the side surface 512 of the first recess portion 51 and the side surface 522 of the second recess portion 52 of the mounting substrate 2 are the curved surfaces, as shown in FIG. 7. Regarding the high frequency module 1 according to Embodiment 4, the same components as the high frequency module 1 according to Embodiment 1 are attached with the same reference numerals, and the description thereof will be omitted.

### (1) Configuration

In the mounting substrate 2 according to Embodiment 4, the side surface 512 of the first recess portion 51 is a curved surface in a plan view in the thickness direction D1 of the mounting substrate 2.

In addition, in the mounting substrate 2 according to Embodiment 4, as shown in FIG. 7, the side surface 522 of the second recess portion 52 is a curved surface in a plan view in the thickness direction D1 of the mounting substrate 2.

Regarding the mounting substrate 2 of Embodiment 4, the same configuration and function as those of the mounting substrate 2 (refer to FIG. 1) of Embodiment 1 will not be described.

### (2) Effects

In the high frequency module 1 according to Embodiment 4, the side surface 512 of the first recess portion 51 is a curved surface in a plan view in the thickness direction D1 of the mounting substrate 2. As a result, the shape of the first recess portion 51 can be made close to the shape of the ground bump 34, and thus the self-alignment amount of the solder can be suppressed within the range of the first recess portion 51 in a case that the power amplifier 3 is disposed on the mounting substrate 2. As a result, the mountability of the power amplifier 3 on the mounting substrate 2 can be improved. That is, the mounting variation of the power amplifier 3 can be reduced.

In the high frequency module 1 according to Embodiment 4, the side surface 522 of the second recess portion 52 is a curved surface in a plan view in the thickness direction D1 of the mounting substrate 2. As a result, the shape of the second recess portion 52 can be made close to the shape of the RF bump 35, and thus the self-alignment amount of the solder can be suppressed within the range of the second recess portion 52 in a case that the power amplifier 3 is disposed on the mounting substrate 2. As a result, the mountability of the power amplifier 3 on the mounting substrate 2 can be improved. That is, the mounting variation of the power amplifier 3 can be reduced.

### (3) Modification Examples

Hereinafter, modification examples of Embodiment 4 will be described.

### (3.1) Modification Example 1

In the high frequency module 1 according to Modification Example 1 of Embodiment 4, among the side surfaces 512 of the first recess portion 51 and the side surfaces 522 of the plurality of second recess portions 52 of the mounting substrate 2, only the side surfaces 512 of the first recess portion 51 are the curved surfaces.

In the high frequency module 1 according to Modification Example 1 of Embodiment 4, the mountability of the power amplifier 3 on the mounting substrate 2 can also be improved.

### (3.2) Modification Example 2

In the high frequency module 1 according to Modification Example 2 of Embodiment 4, among the side surfaces 512 of the first recess portion 51 and the side surfaces 522 of the plurality of second recess portions 52 of the mounting substrate 2, only the side surfaces 522 of the plurality of second recess portion 52 are the curved surfaces. It should be noted that the side surfaces 522 of some of the plurality of second recess portions 52, but not all of the plurality of second recess portions 52 may be curved surfaces.

In the high frequency module 1 according to Modification Example 2 of Embodiment 4, the mountability of the power amplifier 3 on the mounting substrate 2 can also be improved.

In other words, the side surface 512 or 522 of at least one of the first recess portion 51 and the plurality of second recess portions 52 of the mounting substrate 2 may be a curved surface in a plan view in the thickness direction D1 of the mounting substrate 2.

The high frequency module 1 according to each of the above-described modification examples also has the same effects as the high frequency module 1 according to Embodiment 4.

### Embodiment 5

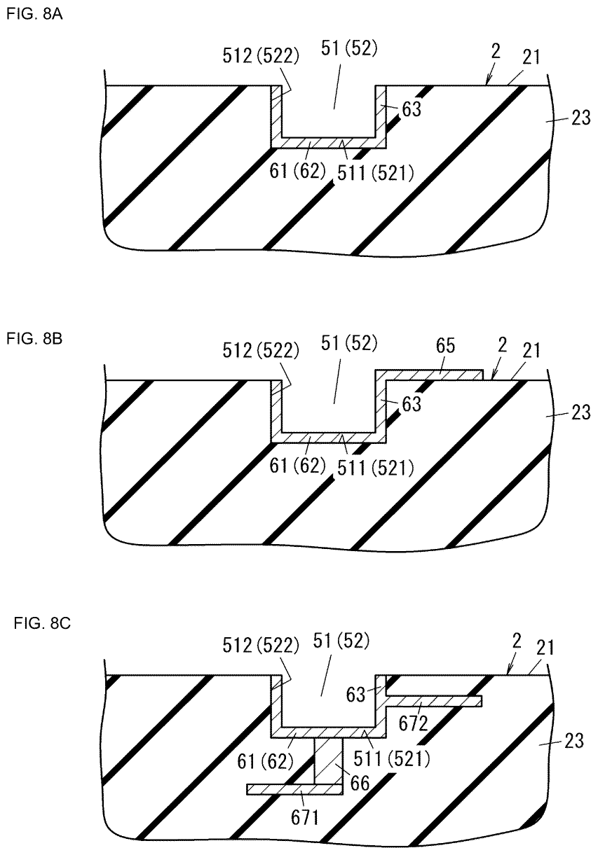

The high frequency module 1 according to Embodiment 5 is different from the high frequency module 1 (refer to FIG. 1) according to Embodiment 1 in that a side surface electrode 63 is formed on the side surface 512 of the first recess portion 51 and the side surfaces 522 of the plurality of second recess portions 52, as shown in FIG. 8A. Regarding the high frequency module 1 according to Embodiment 5, the same components as the high frequency module 1 according to Embodiment 1 are attached with the same reference numerals, and the description thereof will be omitted.

### (1) Configuration

The mounting substrate 2 according to Embodiment 5 further includes the side surface electrode 63, as shown in FIG. 8A. The side surface electrode 63 is formed on the side surface 512 of the first recess portion 51. In addition, the side surface electrode 63 is formed on the side surface 522 of the second recess portion 52. Regarding the mounting substrate 2 of Embodiment 5, the same configuration and function as those of the mounting substrate 2 (refer to FIG. 1) of Embodiment 1 will not be described.

### (2) Effects

In the high frequency module 1 according to Embodiment 5, the first electrode 61 is formed on the bottom surface 511 of the first recess portion 51, and the side surface electrode 63 is formed on the side surface 512 of the first recess portion 51. As a result, the contact area between the ground bump 34 of the power amplifier 3 and the electrodes (the first electrode 61 and the side surface electrode 63) in the first recess portion 51 can be increased, and thus the bonding strength between the ground bump 34 and the electrodes in the first recess portion 51 can be increased. As a result, the mountability of the power amplifier 3 on the mounting substrate 2 can be improved.

In the high frequency module 1 according to Embodiment 5, the side surface electrode 63 is formed on the side surface 512 of the first recess portion 51. As a result, the wiring can be extended from the side surface 512 of the first recess portion 51, and thus the degree of freedom of the wiring can be increased.

In the high frequency module 1 according to Embodiment 5, the second electrode 62 is formed on the bottom surface 521 of the second recess portion 52, and the side surface electrode 63 is formed on the side surface 522 of the second recess portion 52. As a result, the contact area between the RF bump 35 of the power amplifier 3 and the electrodes (the second electrode 62 and the side surface electrode 63) in the second recess portion 52 can be increased, and thus the bonding strength between the RF bump 35 of the power amplifier 3 and the electrodes in the second recess portion 52 can be increased. As a result, the mountability of the power amplifier 3 on the mounting substrate 2 can be improved.

In the high frequency module 1 according to Embodiment 5, the side surface electrode 63 is formed on the side surface 522 of the second recess portion 52. As a result, the wiring can be extended from the side surface 522 of the second recess portion 52, and thus the degree of freedom of the wiring can be increased.

### (3) Modification Examples

Hereinafter, modification examples of Embodiment 5 will be described.

### (3.1) Modification Example 1

In the high frequency module 1 according to Modification Example 1 of Embodiment 5, as shown in FIG. 8B, the mounting substrate 2 includes a wiring pattern conductor 65. The wiring pattern conductor 65 is provided on the first main surface 21 of the mounting substrate 2 to be continuous with the side surface electrode 63.

In the high frequency module 1 according to Modification Example 1 of Embodiment 5, the side surface electrodes 63 are formed on the side surfaces 512 and 522 of at least one of the first recess portion 51 or the second recess portion 52. As a result, the wiring can be extended from the side surfaces 512 and 522 of the recess portions (the first recess portion 51 and the second recess portion 52), and thus the degree of freedom of the wiring can be increased.

### (3.2) Modification Example 2

In the high frequency module 1 according to Modification Example 2 of Embodiment 5, as shown in FIG. 8C, the mounting substrate 2 includes the via conductor 66 and a plurality of wiring pattern conductors 671 and 672.

The via conductor 66 connects the first electrode 61 and the wiring pattern conductor 671. The wiring pattern conductor 672 is connected to the side surface electrode 63. The wiring pattern conductor 672 extends from the side surface electrode 63 in a direction orthogonal to the thickness direction D1 of the mounting substrate 2. The via conductor 66 may be a conductor connecting the second electrode 62 and the wiring pattern conductor 671.

In the high frequency module 1 according to Modification Example 2 of Embodiment 5, the side surface electrodes 63 are formed on the side surfaces 512 and 522 of at least one of the first recess portion 51 or the second recess portion 52. As a result, the wiring can be extended from the side surfaces 512 and 522 of the recess portions (the first recess portion 51 and the second recess portion 52), and thus the degree of freedom of the wiring can be increased.

### (3.3) Modification Example 3

In the high frequency module 1 according to Modification Example 3 of Embodiment 5, among the side surfaces 512 of the plurality of first recess portions 51 and the side surfaces 522 of the plurality of second recess portions 52 of the mounting substrate 2, the side surface electrodes 63 are formed only on the side surfaces 512 of the plurality of first recess portions 51. It should be noted that the side surface electrode 63 may be formed on the side surfaces 512 of some of the plurality of first recess portions 51, but not all of the plurality of first recess portions 51.

In the high frequency module 1 according to Modification Example 3 of Embodiment 5, the degree of freedom of the wiring can also be increased.

### (3.4) Modification Example 4

In the high frequency module 1 according to Modification Example 4 of Embodiment 5, among the side surfaces 512 of the plurality of first recess portions 51 and the side surfaces 522 of the plurality of second recess portions 52 of the mounting substrate 2, the side surface electrodes 63 are formed only on the side surfaces 522 of the plurality of second recess portions 52. It should be noted that the side surface electrode 63 may be formed on the side surfaces 522 of some of the plurality of second recess portions 52, but not all of the plurality of second recess portions 52.

In the high frequency module 1 according to Modification Example 4 of Embodiment 5, the degree of freedom of the wiring can also be increased.

In other words, the mounting substrate 2 need only have the side surface electrode 63 formed on the side surfaces 512 and 522 of at least one of the first recess portion 51 or the second recess portion 52.

The high frequency module 1 according to each of the above-described modification examples also has the same effects as the high frequency module 1 according to Embodiment 5.

### Embodiment 6

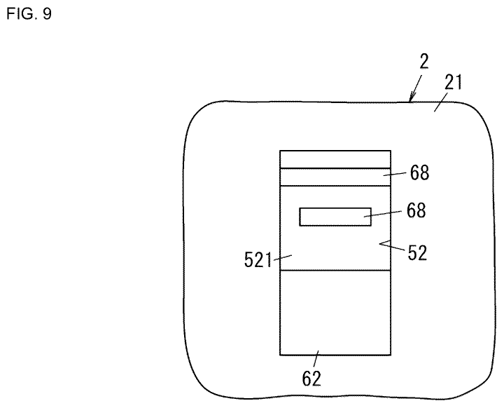

The high frequency module 1 according to Embodiment 6 is different from the high frequency module 1 (refer to FIG. 1) according to Embodiment 1 in that a wiring pattern conductor 68 is formed in the first recess portion 51 and the plurality of second recess portions 52 of the mounting substrate 2, as shown in FIG. 9. Regarding the high frequency module 1 according to Embodiment 6, the same components as the high frequency module 1 according to Embodiment 1 are attached with the same reference numerals, and the description thereof will be omitted.

### (1) Configuration

As shown in FIG. 9, the mounting substrate 2 according to Embodiment 6 includes the plurality of wiring pattern conductors 68. The wiring pattern conductor 68 is formed in the first recess portion 51. More specifically, the wiring pattern conductor 68 is formed on the bottom surface 511 of the first recess portion 51. In addition, as shown in FIG. 9, the wiring pattern conductor 68 is formed on each of the plurality of second recess portions 52. More specifically, the wiring pattern conductor 68 is formed on the bottom surfaces 521 of each of the plurality of second recess portions 52. Regarding the mounting substrate 2 of Embodiment 6, the same configuration and function as those of the mounting substrate 2 (refer to FIG. 1) of Embodiment 1 will not be described.

### (2) Effects

In the high frequency module 1 according to Embodiment 6, the wiring pattern conductor 68 is formed in at least one of the first recess portion 51 or the plurality of second recess portions 52. As a result, the degree of freedom of the wiring can be increased.

### (3) Modification Examples

Hereinafter, modification examples of Embodiment 6 will be described.

### (3.1) Modification Example 1

In the high frequency module 1 according to Modification Example 1 of Embodiment 6, the wiring pattern conductor 68 is formed only in the plurality of first recess portions 51 among the plurality of first recess portions 51 and the plurality of second recess portions 52 of the mounting substrate 2. The wiring pattern conductor 68 may be formed in some of the plurality of first recess portions 51, but not all of the plurality of first recess portions 51.

In the high frequency module 1 according to Modification Example 1 of Embodiment 6, the degree of freedom of the wiring can also be increased.

### (3.2) Modification Example 2

In the high frequency module 1 according to Modification Example 2 of Embodiment 6, the wiring pattern conductor 68 is formed only in the plurality of second recess portions 52 among the plurality of first recess portions 51 and the plurality of second recess portions 52 of the mounting substrate 2. The wiring pattern conductor 68 may be formed in some of the plurality of second recess portions 52, but not all of the plurality of second recess portions 52.

In the high frequency module 1 according to Modification Example 2 of Embodiment 6, the degree of freedom of the wiring can also be increased.

In other words, the mounting substrate 2 need only have the wiring pattern conductor 68 in at least one of the first recess portion 51 or the second recess portion 52.

### (3.3) Modification Example 3

In the high frequency module 1 according to Modification Example 3 of Embodiment 6, the number of the wiring pattern conductors 68 provided in the first recess portion 51 is not limited to two, and may be one or three or more. The number of the wiring pattern conductors 68 provided in the plurality of second recess portions 52 is not limited to two, and may be one or three or more.

The high frequency module 1 according to the modification example described above also has the same effects as the high frequency module 1 according to Embodiment 6.

### Embodiment 7

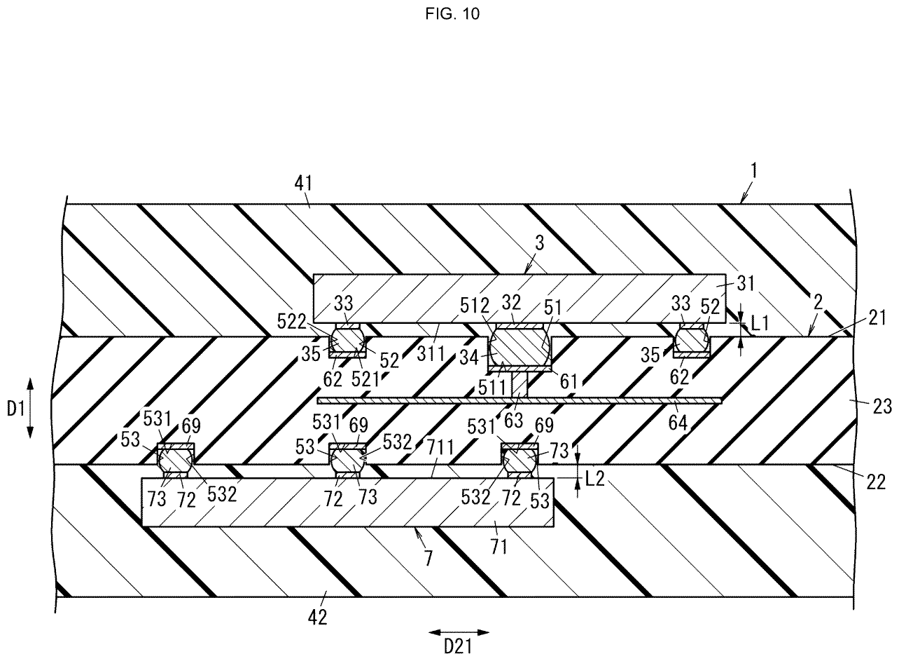

The high frequency module 1 according to Embodiment 7 is different from the high frequency module 1 (refer to FIG. 1) according to Embodiment 1 in that the high frequency module 1 according to Embodiment 7 has a double-sided mounting structure, as shown in FIG. 10. Regarding the high frequency module 1 according to Embodiment 7, the same components as the high frequency module 1 according to Embodiment 1 are attached with the same reference numerals, and the description thereof will be omitted.

### (1) Configuration

The high frequency module 1 according to Embodiment 7 includes the mounting substrate 2, the power amplifier 3, an electronic component 7, the plurality of resin layers 41 and 42, and the plurality of external connection terminals, as shown in FIG. 10.

### (1.1) Mounting Substrate

As shown in FIG. 10, the mounting substrate 2 of Embodiment 7 includes the first main surface 21 and the second main surface 22. The mounting substrate 2 is a double-sided mounting substrate on which an electronic component is mounted on each of the first main surface 21 and the second main surface 22.

### (1.2) Electronic Component

As shown in FIG. 10, the electronic component 7 is disposed on the second main surface 22 of the mounting substrate 2. The electronic component 7 is, for example, an integrated circuit (IC) component. A part of the electronic component 7 is disposed on the second main surface 22 of the mounting substrate 2, and the rest of the electronic component 7 may be incorporated in the mounting substrate 2. In other words, the electronic component 7 is positioned further on the second main surface 22 side of the mounting substrate 2 than the first main surface 21, and has at least a part that is mounted on the second main surface 22.

The electronic component 7 includes a main body portion 71, a plurality of electrodes 72, and a plurality of bumps 73. The electronic component 7 is disposed on the second main surface 22 of the mounting substrate 2 by connecting the plurality of electrode 72 to a plurality of third electrodes 69 provided on the second main surface 22 of the mounting substrate 2 with the plurality of bumps 73 interposed therebetween.

The main body portion 71 has a functional unit. The main body portion 71 is disposed on the mounting substrate 2 such that one main surface 711 of the main body portion 71 faces the mounting substrate 2 in the thickness direction D1 of the mounting substrate 2. More specifically, one main surface 711 of the main body portion 71 faces the second main surface 22 of the mounting substrate 2 in a state where the electronic component 7 is disposed on the mounting substrate 2.

The plurality of electrodes 72 are formed on one main surface 711 of the main body portion 71. The plurality of electrodes 72 are provided, for example, on one main surface 711 of the main body portion 71 at intervals from each other.

The plurality of bumps 73 are bumps for connecting the plurality of electrodes 72 to the conductive layer of the mounting substrate 2. The plurality of bumps 73 are disposed on the plurality of electrodes 72. Each bump 73 is formed in, for example, a circular shape. Each bump 73 is formed of, for example, solder.

In a case where the electronic component 7 is an IC component, the electronic component 7 includes, for example, a low noise amplifier and a switch. In a plan view of the mounting substrate 2 in the thickness direction D1, the outer peripheral shape of the electronic component 7 is a quadrangular shape.

The low noise amplifier includes an input terminal and an output terminal. The low noise amplifier amplifies the reception signal input to the input terminal and outputs the amplified reception signal from the output terminal. The input terminal of the low noise amplifier is connected to a common terminal of the switches with an input matching circuit interposed therebetween. The output terminal of the low noise amplifier is connected to a signal output terminal. Therefore, the output terminal of the low noise amplifier is connected to the signal processing circuit 82 with the signal output terminal interposed therebetween.

The switch includes a common terminal and a plurality of selection terminals. The switch is controlled by a controller. The switch switches a connection state between the common terminal and the plurality of selection terminals in response to a control signal from the controller.

Examples of the switch included in the IC component include a first switch, a second switch, and a third switch.

The first switch is an antenna switch connected to an antenna terminal. The common terminal is connected to the antenna terminal. An antenna (not shown) is connected to the antenna terminal. The selection terminal is connected to, for example, a transmission filter or a reception filter. The first switch is a switch that is capable of connecting at least one or more of the plurality of selection terminals to the common terminal. The first switch is, for example, a switch capable of one-to-one and one-to-many connections.

The second switch is, for example, a band select switch for switching signal paths for a plurality of transmission signals having different communication bands from each other. The second switch includes a common terminal and a plurality of selection terminals. The common terminal is connected to the power amplifier 3. The selection terminal is connected to the transmission filter. The second switch is a switch that is capable of connecting at least one or more of the plurality of selection terminals to the common terminal. The second switch is, for example, a switch capable of one-to-one and one-to-many connections.

The third switch includes a common terminal and a plurality of selection terminals. The common terminal is connected to the low noise amplifier with the input matching circuit interposed therebetween. The selection terminal is connected to the reception filter. The third switch is a switch that is capable of connecting at least one or more of the plurality of selection terminals to the common terminal. The third switch is, for example, a switch capable of one-to-one and one-to-many connections.

### (1.3) Arrangement Relationship of Mounting Substrate, Power Amplifier, and Electronic Component

As shown in FIG. 10, the mounting substrate 2 includes the first recess portion 51, the plurality of second recess portions 52, and a plurality of third recess portions 53. The plurality of third recess portions 53 are formed on the second main surface 22 of the mounting substrate 2. Each of the plurality of third recess portions 53 includes a bottom surface 531 and a side surface 532. Similarly to the first recess portion 51 and the plurality of second recess portions 52 of Embodiment 1 (refer to FIG. 1), the first recess portion 51 and the plurality of second recess portions 52 are formed on the first main surface 21 of the mounting substrate 2.

The mounting substrate 2 includes the first electrode 61, the plurality of second electrodes 62, and the plurality of third electrodes 69. The plurality of third electrodes 69 are disposed on the bottom surfaces 531 of the plurality of third recess portions 53. Similarly to the first electrode 61 and the plurality of second electrodes 62 (refer to FIG. 1) of Embodiment 1, the first electrode 61 is disposed on the bottom surface 511 of the first recess portion 51, and the plurality of second electrodes 62 are disposed on the bottom surfaces 521 of the plurality of second recess portions 52.

The plurality of bumps 73 of the electronic component 7 are disposed in the plurality of third recess portions 53 of the mounting substrate 2. More specifically, in each of the plurality of bumps 73, the bump 73 is disposed in the third recess portion 53 such that at least a part of the bump 73 is accommodated in the third recess portion 53.

Since the plurality of bumps 73 of the electronic component 7 are disposed in the plurality of third recess portions 53 of the mounting substrate 2, it is possible to reduce the height of the electronic component 7 from the surface of the second main surface 22 of the mounting substrate 2 on which the plurality of third recess portions 53 are not formed, and thus it is possible to achieve low profile of the high frequency module 1.

In the mounting substrate 2 according to Embodiment 7, at least one of the plurality of third recess portions 53 overlaps with the second recess portion 52 in a plan view in the thickness direction D1 of the mounting substrate 2. In the example of FIG. 10, the central third recess portion 53 of the three third recess portions 53 overlaps with the second recess portion 52 on the left side of the two second recess portions 52 in a plan view in the thickness direction D1 of the mounting substrate 2.

In addition, in the mounting substrate 2 of Embodiment 7, at least one of the plurality of third recess portions 53 overlaps with the first recess portion 51 in a plan view in the thickness direction D1 of the mounting substrate 2. In the example of FIG. 10, the rightmost third recess portion 53 among the three third recess portions 53 overlaps with the first recess portion 51 in a plan view in the thickness direction D1 of the mounting substrate 2.

### (1.4) Resin Layer

As shown in FIG. 10, the resin layer 41 is disposed on the first main surface 21 of the mounting substrate 2. The resin layer 41 is in contact with the first main surface 21 of the mounting substrate 2 and covers at least a part of the power amplifier 3. As a result, the mounting substrate 2 and the power amplifier 3 can be protected.

The resin layer 41 contains a resin and a filler. The resin is, for example, an epoxy resin. In the high frequency module 1, the distance L1 between the main body portion 31 of the power amplifier 3 and the mounting substrate 2 is larger than the diameter of the filler contained in the resin layer 41. As a result, the resin layer 41 intrudes into the periphery of the bump (the ground bump 34 and the RF bump 35) of the power amplifier 3, and thus the solder splash can be prevented in a case that the high frequency module 1 is mounted on the motherboard. As a result, it is possible to improve the connection reliability of the power amplifier 3.

As shown in FIG. 10, the resin layer 42 is disposed on the second main surface 22 of the mounting substrate 2. The resin layer 42 covers at least a part of each of the plurality of electronic components (including the electronic component 7) disposed on the second main surface 22 of the mounting substrate 2. More specifically, the resin layer 42 covers an outer peripheral surface of each electronic component and a main surface of each electronic component on a side opposite to the mounting substrate 2 side. The resin layer 42 contains a resin. The resin is, for example, an epoxy resin. The resin layer 42 may contain a filler in addition to the resin. A material of the resin layer 42 may be the same material as the material of the resin layer 41 or may be a different material.

As shown in FIG. 10, the resin layer 42 is disposed on the second main surface 22 of the mounting substrate 2. The resin layer 42 is in contact with the second main surface 22 of the mounting substrate 2 and covers at least a part of the electronic component 7. As a result, the mounting substrate 2 and the electronic component 7 can be protected.

The resin layer 42 contains a resin and a filler. The resin is, for example, an epoxy resin. In the high frequency module 1, a distance L2 between the main body portion 71 of the electronic component 7 and the mounting substrate 2 is larger than the diameter of the filler contained in the resin layer 42. As a result, the resin layer 42 intrudes into the periphery of the bump 73 of the electronic component 7, and thus it is possible to prevent the solder splash in a case that mounting the high frequency module 1 on the motherboard. As a result, it is possible to improve the connection reliability of the electronic component 7.

### (1.5) External Connection Terminal

The plurality of external connection terminals are disposed on the second main surface 22 of the mounting substrate 2, for example. The plurality of external connection terminals are arranged on the second main surface 22 of the mounting substrate 2 at intervals from each other.

Each of the plurality of external connection terminals is a columnar (for example, cylindrical) conductive member. Materials of the plurality of external connection terminals are, for example, metal (for example, copper, copper alloy, or the like). The tip end portion of each of the plurality of external connection terminals may include, for example, a gold plating layer.

### (2) Effects

In a high frequency module 1 according to Embodiment 7, an electronic component 7 is disposed on the second main surface 22 of the mounting substrate 2. As a result, the mounting efficiency of the high frequency module 1 can be enhanced.

In the high frequency module 1 according to Embodiment 7, the bump 73 of the electronic component 7 is disposed in the third recess portion 53 of the mounting substrate 2. As a result, the recess portions (the first recess portion 51, the second recess portion 52, and the third recess portion 53) are formed on both surfaces on the first main surface 21 side and the second main surface 22 side of the mounting substrate 2, the bumps (the ground bump 34, the RF bump 35, and the bump 73 of the electronic component 7) are disposed in the recess portions, and thus it is possible to further achieve low profile of the high frequency module 1.

In the high frequency module 1 according to Embodiment 7, the first recess portion 51, the second recess portion 52, and the third recess portion 53 are formed on the mounting substrate 2. As a result, the distance between the RF bump 35 of the power amplifier 3 and the bump 73 of the electronic component 7 can be made shorter than in a case where the first recess portion 51, the second recess portion 52, and the third recess portion 53 are not formed, and thus the wiring length can be made shorter. As a result, it is possible to reduce the loss of the wiring.

In the high frequency module 1 according to Embodiment 7, the third recess portion 53 overlaps with the second recess portion 52 in the thickness direction D1 of the mounting substrate 2. As a result, the distance between the RF bump 35 of the power amplifier 3 and the bump 73 of the electronic component 7 can be made much shorter. As a result, it is possible to further reduce the loss of the wiring.

In the high frequency module 1 according to Embodiment 7, the first recess portion 51, the second recess portion 52, and the third recess portion 53 are formed on the mounting substrate 2. As a result, the thickness of the mounting substrate 2 can be increased while the height of the high frequency module 1 is maintained, as compared with the case where the first recess portion 51, the second recess portion 52, and the third recess portion 53 are not formed in the mounting substrate 2, and thus the strength of the mounting substrate 2 can be increased.

### (3) Modification Examples

Hereinafter, modification examples of Embodiment 7 will be described.

### (3.1) Modification Example 1

The high frequency module 1 according to Modification Example 1 of Embodiment 7 includes the mounting substrate 2, the power amplifier 3, the electronic component 7, the plurality of resin layers 41 and 42, the plurality of external connection terminals, and the shield layer.

The shield layer covers at least a part of the resin layers 41 and 42 and the mounting substrate 2. More specifically, the shield layer covers one main surface and an outer peripheral surface of the resin layer 41, an outer peripheral surface of the mounting substrate 2, and an outer peripheral surface of the resin layer 42. One main surface of the resin layer 41 is a main surface on a side opposite to the mounting substrate 2 side in the resin layer 41. Regarding the shield layer of Modification Example 1 of Embodiment 7, the same configuration and function as those of the shield layer of Modification Example 1 of Embodiment 1 will not be described.

### (3.2) Modification Example 2

In the high frequency module 1 according to Modification Example 2 of Embodiment 7, the electronic component 7 is not an IC component including the low noise amplifier and the switch, but is another component other than the IC component. The electronic component 7 may be, for example, only a low noise amplifier or only a switch.

The high frequency module 1 according to each of the above-described modification examples also has the same effects as the high frequency module 1 according to Embodiment 7.

The embodiments and the modification examples described above are merely a part of various embodiments and modification examples of the present disclosure. In addition, in the embodiment and the modification example, various changes can be made according to the design or the like as long as the exemplary embodiments of the present disclosure can be achieved.

### Aspects

The following aspects are disclosed in the present specification.

A high frequency module (1) according to a first aspect includes: a mounting substrate (2); and a power amplifier (3). The mounting substrate (2) includes a first main surface (21) and a second main surface (22). The first main surface (21) and the second main surface (22) face each other. The power amplifier (3) is disposed on the first main surface (21) of the mounting substrate (2), and includes an RF bump (35) and a ground bump (34). The ground bump (34) is higher than the RF bump (35). The mounting substrate (2) includes a first recess portion (51). The first recess portion (51) is formed on the first main surface (21) of the mounting substrate (2). The ground bump (34) is disposed in the first recess portion (51) of the mounting substrate (2).

With the high frequency module (1) according to the first aspect, it is possible to achieve low profile of the high frequency module (1).

With the high frequency module (1) according to the first aspect, the distance between the power amplifier (3) and the wiring conductor or the wiring element built in the mounting substrate (2) can be made shorter than in a case where the first recess portion (51) is not formed.

In the high frequency module (1) according to a second aspect, in the first aspect, the mounting substrate (2) further includes a second recess portion (52). The second recess portion (52) is formed on the first main surface (21) of the mounting substrate (2). The RF bump (35) of the power amplifier (3) is disposed in the second recess portion (52) of the mounting substrate (2).

With the high frequency module (1) according to the second aspect, the height of the power amplifier (3) from the surface of the first main surface (21) of the mounting substrate (2) on which the first recess portion (51) and the second recess portion (52) are not formed can be reduced, and thus it is possible to achieve low profile of the high frequency module (1).

With the high frequency module (1) according to the second aspect, the distance between the power amplifier (3) and the wiring conductor or the wiring element built in the mounting substrate (2) can be made shorter than in a case where the second recess portion (52) is not formed.

In the high frequency module (1) according to a third aspect, in the second aspect, the first recess portion (51) and the second recess portion (52) are continuous to each other.

With the high frequency module (1) according to the third aspect, it is not necessary to form a wall between the first recess portion (51) and the second recess portion (52), and thus the first recess portion (51) and the second recess portion (52) can be easily formed.

With the high frequency module (1) according to the third aspect, the first recess portion (51) and the second recess portion (52) can be formed even in a case where the distance between the two adjacent electrodes (32, 33) of the power amplifier (3) is short, that is, in a case where the distance between the ground bump (34) and the RF bump (35) is short.

In the high frequency module (1) according to a fourth aspect, in the second aspect, a side surface (522) of the second recess portion (52) of the mounting substrate (2) is a curved surface in a plan view in the thickness direction (D1) of the mounting substrate (2).

With the high frequency module (1) according to the fourth aspect, the shape of the second recess portion (52) can be made close to the shape of the RF bump (35), and thus the self-alignment amount of the solder can be suppressed within the range of the second recess portion (52) in a case that the power amplifier (3) is disposed on the mounting substrate (2). As a result, the mountability of the power amplifier (3) on the mounting substrate (2) can be improved. That is, the mounting variation of the power amplifier (3) can be reduced.

In the high frequency module (1) according to a fifth aspect, in the second aspect, the mounting substrate (2) includes a wiring pattern conductor (68). The wiring pattern conductor (68) is formed in at least one of the first recess portion (51) and the second recess portion (52).

With the high frequency module (1) according to the fifth aspect, the degree of freedom of the wiring can be increased.

In the high frequency module (1) according to a sixth aspect, in the second aspect, the mounting substrate (2) includes a side surface electrode (63). The side surface electrode (63) is formed on the side surface (522) of the second recess portion (52).

With the high frequency module (1) according to the sixth aspect, the contact area between the RF bump (35) of the power amplifier (3) and the electrode in the second recess portion (52) can be increased, and thus the bonding strength between the RF bump (35) of the power amplifier (3) and the electrode in the second recess portion (52) can be increased. As a result, the mountability of the power amplifier (3) on the mounting substrate (2) can be improved.

With the high frequency module (1) according to the sixth aspect, the wiring can be extended from the side surface (522) of the second recess portion (52), and thus the degree of freedom of the wiring can be increased.

In the high frequency module (1) according to a seventh aspect, in the first aspect, the RF bump (35) of the power amplifier (3) is disposed at a part of the first main surface (21) of the mounting substrate (2) in which the recess portion is not formed.

With the high frequency module (1) according to the seventh aspect, it is possible to simplify the processing of forming the recess portion with respect to the mounting substrate (2).

In the high frequency module (1) according to an eighth aspect, in any one of the first to seventh aspects, the mounting substrate (2) includes a via conductor (66). The via conductor (66) is connected to the first recess portion (51) in which the ground bump (34) is disposed.

With the high frequency module (1) according to the eighth aspect, the length of the via conductor (66) can be made shorter than in a case where the first recess portion (51) is not formed, and thus, for example, the distance between the ground bump (34) and a ground layer (64) of the mounting substrate (2) can be made shorter.

In the high frequency module (1) according to a ninth aspect, in any one of the first to eighth aspects, a side surface (512) of the first recess portion (51) of the mounting substrate (2) is a curved surface in a plan view in the thickness direction (D1) of the mounting substrate (2).

With the high frequency module (1) according to the ninth aspect, the shape of the first recess portion (51) can be made close to the shape of the ground bump (34), and thus the self-alignment amount of the solder can be suppressed within the range of the first recess portion (51) in a case that the power amplifier (3) is disposed on the mounting substrate (2). As a result, the mountability of the power amplifier (3) on the mounting substrate (2) can be improved. That is, the mounting variation of the power amplifier (3) can be reduced.

In the high frequency module (1) according to a tenth aspect, in any one of the first to ninth aspects, the mounting substrate (2) includes the side surface electrode (63). The side surface electrode (63) is formed on the side surface (512) of the first recess portion (51).

With the high frequency module (1) according to the tenth aspect, the contact area between the ground bump (34) of the power amplifier (3) and the electrode in the first recess portion (51) can be increased, and thus the bonding strength between the ground bump (34) and the electrode in the first recess portion (51) can be increased. As a result, the mountability of the power amplifier (3) on the mounting substrate (2) can be improved.

With the high frequency module (1) according to the tenth aspect, the wiring can be extended from the side surface (512) of the first recess portion (51), and thus the degree of freedom of the wiring can be increased.

In any one of the third to tenth aspects, the high frequency module (1) according to an eleventh aspect further includes an electronic component (7). The electronic component (7) is disposed on the second main surface (22) of the mounting substrate (2) and includes a bump (73).

With the high frequency module (1) according to the eleventh aspect, the mounting efficiency of the high frequency module (1) can be enhanced.

In the high frequency module (1) according to a twelfth aspect, in the eleventh aspect, the mounting substrate (2) further includes a third recess portion (53). The third recess portion (53) is formed on the second main surface (22). The bump (73) of the electronic component (7) is disposed in the third recess portion (53) of the mounting substrate (2).

With the high frequency module (1) according to the twelfth aspect, the recess portions (the first recess portion 51, the second recess portion 52, and the third recess portion 53) are formed on both surfaces on the first main surface (21) side and the second main surface (22) side of the mounting substrate (2), the bumps (the ground bump 34, the RF bump 35, and the bump 73 of the electronic component 7) are disposed in the recess portions, and thus it is possible to further achieve low profile of the high frequency module (1).

With the high frequency module (1) according to the twelfth aspect, the distance between the RF bump (35) of the power amplifier (3) and the bump (73) of the electronic component (7) can be made shorter than in a case where the first recess portion (51), the second recess portion (52), and the third recess portion (53) are not formed, and thus the wiring length can be made shorter. As a result, it is possible to reduce the loss of the wiring.

In the high frequency module (1) according to the thirteenth aspect, in the twelfth aspect, the mounting substrate (2) further includes the second recess portion (52). The second recess portion (52) is formed on the first main surface (21) of the mounting substrate (2). The RF bump (35) of the power amplifier (3) is disposed in the second recess portion (52) of the mounting substrate (2). The third recess portion (53) of the mounting substrate (2) overlaps with the second recess portion (52) of the mounting substrate (2) in a plan view in the thickness direction (D1) of the mounting substrate (2).

With the high frequency module (1) according to the thirteenth aspect, the distance between the RF bump (35) of the power amplifier (3) and the bump (73) of the electronic component (7) can be further made shorter. As a result, it is possible to further reduce the loss of the wiring.

In any one of the first to thirteenth aspects, the high frequency module (1) according to a fourteenth aspect further includes a resin layer (41). The resin layer (41) is in contact with the first main surface (21) of the mounting substrate (2) and covers at least a part of the power amplifier (3).

With the high frequency module (1) according to the fourteenth aspect, the mounting substrate (2) and the power amplifier (3) can be protected.

In the high frequency module (1) according to a fifteenth aspect, in the fourteenth aspect, the resin layer (41) contains a filler. A distance (L1) between the power amplifier (3) and the mounting substrate (2) is larger than the diameter of the filler contained in the resin layer (41).

With the high frequency module (1) according to the fifteenth aspect, the resin layer (41) intrudes into the periphery of the bump of the power amplifier (3), it is possible to prevent the solder splash while mounting the high frequency module (1) on the motherboard. As a result, the connection reliability of the power amplifier (3) can be improved.

In the high frequency module (1) according to a sixteenth aspect, in the fourteenth aspect, the resin layer (41) contains a filler. The distance (L1) between the power amplifier (3) and the mounting substrate (2) is smaller than a diameter of the filler contained in the resin layer (41).

With the high frequency module (1) according to the sixteenth aspect, it is possible to further achieve low profile of the high frequency module (1).

In any one of the fourteenth to sixteenth aspects, the high frequency module (1) according to a seventeenth aspect further includes a shield layer. The shield layer covers at least a part of the resin layer (41) and the mounting substrate (2). The mounting substrate (2) has the ground layer (64). The shield layer is in contact with at least a part of the ground layer (64).

With the high frequency module (1) according to the seventeenth aspect, the potential of the shield layer can be set to be the same as the potential of the ground layer (64).

In the high frequency module (1) according to an eighteenth aspect, in any one of the first to seventeenth aspects, the power amplifier (3) further includes a main body portion (31) having a functional unit. The main body portion (31) of the power amplifier (3) is positioned outside the mounting substrate (2).

With the high frequency module (1) according to the eighteenth aspect, the strength of the mounting substrate (2) can be increased as compared with a case where the recess portion accommodating the main body portion (31) of the power amplifier (3) is formed in the mounting substrate (2).

A communication device (8) according to the nineteenth aspect includes the high frequency module (1) according to any one of the first to eighteenth aspects, and a signal processing circuit (82). The signal processing circuit (82) is connected to the high frequency module (1).

With the communication device (8) according to the nineteenth aspect, it is possible to achieve low profile of the high frequency module (1).

What is claimed is:

1. A high frequency module comprising:
a mounting substrate including a first main surface and a second main surface that face each other; and
a power amplifier that is disposed on the first main surface of the mounting substrate and includes an RF bump and a ground bump which is higher than the RF bump, wherein
the mounting substrate includes a first recess portion formed on the first main surface of the mounting substrate, and
the ground bump is disposed in the first recess portion of the mounting substrate.

2. The high frequency module according to claim 1, wherein
the mounting substrate further includes a second recess portion formed on the first main surface of the mounting substrate, and
the RF bump of the power amplifier is disposed in the second recess portion of the mounting substrate.

3. The high frequency module according to claim 2, wherein
the first recess portion and the second recess portion are continuous to each other.

4. The high frequency module according to claim 2, wherein
a side surface of the second recess portion of the mounting substrate is a curved surface in a plan view in a thickness direction of the mounting substrate.

5. The high frequency module according to claim 2, wherein
the mounting substrate includes a wiring pattern conductor formed in at least one of the first recess portion and the second recess portion.

6. The high frequency module according to claim 2, wherein
the mounting substrate includes a side surface electrode formed on a side surface of the second recess portion.

7. The high frequency module according to claim 1, wherein
the RF bump of the power amplifier is disposed at a part of the first main surface of the mounting substrate in which the recess portion is not formed.

8. The high frequency module according to claim 1, wherein
the mounting substrate includes a via conductor connected to the first recess portion in which the ground bump is disposed.

9. The high frequency module according to claim 1, wherein
a side surface of the first recess portion of the mounting substrate is a curved surface in a plan view in a thickness direction of the mounting substrate.

10. The high frequency module according to claim 1, wherein
the mounting substrate includes a side surface electrode formed on a side surface of the first recess portion.

11. The high frequency module according to claim 3, further comprising:
an electronic component that is disposed on the second main surface of the mounting substrate and includes a bump.

12. The high frequency module according to claim 11, wherein
the mounting substrate further includes a third recess portion formed on the second main surface, and
the bump of the electronic component is disposed in the third recess portion of the mounting substrate.

13. The high frequency module according to claim 12, wherein
the mounting substrate further includes a second recess portion formed on the first main surface of the mounting substrate,
the RF bump of the power amplifier is disposed in the second recess portion of the mounting substrate, and
the third recess portion of the mounting substrate overlaps with the second recess portion of the mounting substrate in a plan view in a thickness direction of the mounting substrate.

14. The high frequency module according to claim 1, further comprising:
a resin layer that is in contact with the first main surface of the mounting substrate and covers at least a part of the power amplifier.

15. The high frequency module according to claim 14, wherein
the resin layer contains a filler, and
a distance between the power amplifier and the mounting substrate is larger than a diameter of the filler contained in the resin layer.

16. The high frequency module according to claim 14, wherein
the resin layer contains a filler, and
a distance between the power amplifier and the mounting substrate is smaller than a diameter of the filler contained in the resin layer.

17. The high frequency module according to claim 14, further comprising:
a shield layer that covers at least a part of the resin layer and the mounting substrate, wherein
the mounting substrate has a ground layer, and
the shield layer is in contact with at least a part of the ground layer.

18. The high frequency module according to claim 1, wherein
the power amplifier further includes a main body portion having a functional unit having at least one transistor formed on the first surface of the substrate, and
the main body portion of the power amplifier is positioned outside the mounting substrate.

19. A communication device comprising:
a high frequency module including
a mounting substrate including a first main surface and a second main surface that face each other; and
a power amplifier that is disposed on the first main surface of the mounting substrate and includes an RF bump and a ground bump which is higher than the RF bump, wherein
the mounting substrate includes a first recess portion formed on the first main surface of the mounting substrate, and
the ground bump is disposed in the first recess portion of the mounting substrate; and
a signal processing circuit connected to the high frequency module.
